(19) United States
(12) Patent Application Publication
(10) Pub. No.: US 2026/0326123 A1
(43) Pub. Date: Oct. 22, 2026

(54) LIQUID MATERIAL VAPORIZER AND LIQUID MATERIAL VAPORIZATION METHOD

(71) Applicant: HORIBA STEC, Co., Ltd., Kyoto-shi, Kyoto (JP)

(72) Inventor: Keisuke NISHIWAKI, Kyoto-shi (JP)

(21) Appl. No.: 19/113,097

(22) PCT Filed: Oct. 2, 2023
(86) PCT No.: PCT/JP2023/035869

§ 371 Date: Mar. 19, 2025

(30) Foreign Application Priority Data
Oct. 12, 2022 (JP) 2022-163787

(51) Int. Cl. B05B 7/04; B05B 7/16

(52) U.S. Cl. CPC B05B 7/0416; B05B 7/16

(57) ABSTRACT

A liquid material vaporizer includes a gas-liquid mixing portion for mixing together a liquid material and a carrier gas to produce a gas-liquid mixture, a carrier gas feeding passage for feeding the carrier gas to the gas-liquid mixing portion, a flow passage through which the gas-liquid mixture produced in the gas-liquid mixing portion flows, a vaporization portion for heating and vaporizing the liquid material in the gas-liquid mixture flowing through the flow passage, and a cooling portion for cooling the flow passage. The cooling portion communicates with the carrier gas feeding passage.

### TECHNICAL FIELD

The present invention relates to a liquid material vaporizer and a method for vaporizing liquid material.

### BACKGROUND ART

In a liquid material vaporizer (hereinafter, also referred to as “vaporizer”) employing a DLI (direct liquid injection) system, a gas-liquid mixture obtained by mixing a liquid material with a carrier gas is atomized into a vaporizing chamber through a nozzle to vaporize the liquid material. For thorough vaporization of the liquid material in the vaporizing chamber, the vaporizing chamber is heated by a heater.

If heating results in high temperature in the vaporizing chamber, the heat in the vaporizing chamber is prone to transmit to the gas-liquid mixture to be atomized. This arouses concern of the liquid material in the gas-liquid mixture being thermally decomposing or degenerating before being vaporized in the vaporizing chamber.

With regard to this concern, Patent Document 1, for example, discloses a vaporizer comprising a cooling structure for cooling a nozzle. The cooling structure includes a refrigerant passage through which refrigerant passes. Usable as the refrigerant is water or coolant. The refrigerant passing through the refrigerant passage cools the nozzle. This suppresses volatilization, caused by heat in the vaporizing chamber, of the liquid material to be atomized.

### CITATION LIST

### Patent Literature

Patent Document 1: Japanese Patent disclosed as No. 2005-109348

### SUMMARY OF INVENTION

### Technical Problem

Inconveniently, the cooling structure in the vaporizer according to Patent Document 1 requires the use of, in addition to the carrier gas for mixing with the liquid material, refrigerant dedicated to cooling the target to be cooled, that is, the nozzle. It thus requires extra equipment to be installed for introducing the refrigerant and for disposing of the refrigerant after cooling the nozzle. This may lead to an increased size of semiconductor processing equipment that incorporates the vaporizer. Further, the installation of the equipment for introducing and disposing of the refrigerant may also result in an increased cost.

The present invention is made to cope with the above drawback, and an object of the present invention is to provide a liquid material vaporizer, and also a method for vaporizing a liquid material, that can effectively use a carrier gas for mixing with the liquid material also as a gas for cooling a target to be cooled and that can thereby suppress an increase in the size and cost of semiconductor processing equipment.

### Solution to Problem

According to one aspect of the present invention, a liquid material vaporizer includes a gas-liquid mixing portion for mixing together a liquid material and a carrier gas to produce a gas-liquid mixture, a carrier gas feeding passage for feeding the carrier gas to the gas-liquid mixing portion, a flow passage through which the gas-liquid mixture produced in the gas-liquid mixing portion flows, a vaporization portion for heating and vaporizing the liquid material in the gas-liquid mixture flowing through the flow passage, and a cooling portion for cooling the flow passage. The cooling portion communicates with the carrier gas feeding passage.

According to another aspect of the present invention, a liquid material vaporization method includes a gas-liquid mixture producing step of mixing together a liquid material and a carrier gas in a gas-liquid mixing portion to produce a gas-liquid mixture, a vaporizing step of heating and vaporizing, in a vaporization portion, the liquid material in the gas-liquid mixture produced in the gas-liquid mixing portion and fed through a flow passage to the vaporization portion, a cooling step of cooling the flow passage by feeding the carrier gas, and a carrier gas feeding step of feeding the carrier gas having cooled the flow passage in the cooling step via a carrier gas feeding passage to the gas-liquid mixing portion.

### Advantageous Effects of Invention

According to one aspect of the present invention, it is possible to effectively use a carrier gas for mixing with a liquid material also as a gas for cooling an object to be cooled, and thereby to suppress an increase in the size and cost of semiconductor processing equipment incorporating a liquid material vaporizer.

### BRIEF DESCRIPTION OF DRAWINGS

FIG. 1 is a schematic sectional view of a general structure of a liquid material vaporizer according to an embodiment of the present invention.

FIG. 2 is a flow chart showing the sequence of steps in a liquid material vaporization method for vaporizing a liquid material using the liquid material vaporizer.

FIG. 3 is a sectional view of a cooling portion in the liquid material vaporizer as cut along a section perpendicular to the flowing direction of a gas-liquid mixture in a connection portion.

FIG. 4 is a schematic sectional view of another structure of the liquid material vaporizer.

FIG. 5 is a schematic sectional view of still another structure of the liquid material vaporizer.

FIG. 6 is a schematic sectional view of yet another structure of the liquid material vaporizer.

### DESCRIPTION OF EMBODIMENTS

Now, an illustrative embodiment of the present invention will be described with reference to the accompanying drawings.

### 1. Liquid Material Vaporizer

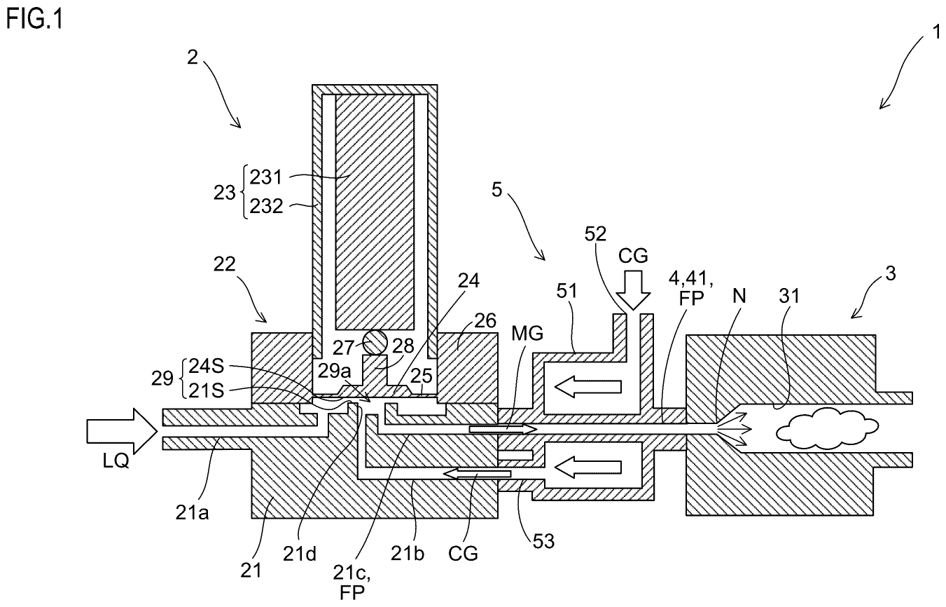

FIG. 1 is a schematic sectional view of a general structure of a liquid material vaporizer 1 according to an embodiment. The liquid material vaporizer 1 is incorporated, for example, in semiconductor manufacturing equipment (not shown). The liquid material vaporizer 1 includes a flow control valve 2, a vaporization portion 3, a connection portion 4, and a cooling portion 5.

### 1-1. Flow Control Valve

The flow control valve 2 is a mechanism that regulates the flow rate of a fluid (gas or liquid) to be used and constitutes a part of, for example, a mass flow controller (flow control device). The flow control valve 2 is configured, for example, as a normal open type and includes a body block 21, a support block 22, and an actuator 23.

The body block 21 is formed of a metal material such as stainless steel. The body block 21 has a valve seat surface 21S. A seating surface 24S of a valving element 24, which will be described later, makes contact with the valve seat surface 21S or separates from it (moves into or out of it).

In the body block 21, a liquid material feeding passage 21a, a carrier gas feeding passage 21b, and a gas-liquid mixture discharging passage 21c are formed. The liquid material feeding passage 21a is a passage for feeding a liquid material LQ to be vaporized in the vaporization portion 3 to a gas-liquid mixing portion 29, which will be described later. The carrier gas feeding passage 21b is a passage for feeding a carrier gas CG to the gas-liquid mixing portion 29. Usable as the carrier gas CG is an inert gas such as nitrogen gas or argon gas. The gas-liquid mixture discharging passage 21c is a passage for discharging a gas-liquid mixture MG produced in the gas-liquid mixing portion 29. The gas-liquid mixture MG is a mixture of the liquid material LQ and the carrier gas CG. The carrier gas feeding passage 21b and the gas-liquid mixture discharging passage 21c communicate with each other via a communication passage 21d provided in the valve seat surface 21S.

The support block 22 includes the valving element 24. The valving element 24 is a movable member that moves along a contact/separation direction (e.g. up/down direction) with respect to the valve seat surface 21S of the body block 21 and has the seating surface 24S that comes into contact with the valve seat surface 21S. The valving element 24 is supported on a supporting member 26 via a diaphragm 25 in a direction (e.g., horizontal direction) intersecting with the contact/separation direction. The supporting member 26 is fastened to the body block 21, for example, with a bolt.

The actuator 23 is a driving portion that moves the valving element 24 in the contact/separation direction. The actuator 23 includes, for example, a piezoelectric stack 231. The piezoelectric stack 231 is formed by stacking on each other a plurality of piezoelectric elements that expands on application of an electric voltage. The piezoelectric stack 231 is housed in a housing member 232 and applies a pressing force to the valving element 24 via a spherical member 27 and a plunger 28. The housing member 232 is fixed to the supporting member 26.

The flow control valve 2 further includes the gas-liquid mixing portion 29. In the gas-liquid mixing portion 29, the liquid material LQ and the carrier gas CG are mixed to produce the gas-liquid mixture MG. Such mixing of the liquid material LQ with the carrier gas CG is carried out in a space between the valve seat surface 21S of the body block 21 and the seating surface 24S of the valving element 24. Here, this space is referred to as the gas-liquid mixing chamber 29a. Thus, the gas-liquid mixing portion 29 includes the gas-liquid mixing chamber 29a.

The gas-liquid mixing chamber 29a is a space lying between the valve seat surface 21S and the seating surface 24S, and the valve seat surface 21S and the seating surface 24S together form the gas-liquid mixing chamber 29a. Thus, it can be understood that the gas-liquid mixing portion 29 is configured to include the valve seat surface 21S and the seating surface 24S that form the gas-liquid mixing chamber 29a.

In the above configuration, in a state where no voltage is applied to the piezoelectric stack 231, the openness of the valve (the gap between the valve seat surface 21S and the seating surface 24S) is set at a predetermined value. In this state, an urging member not shown urges the valving element 24 together with the plunger 28 in a first direction. The first direction is, for example, a direction (e.g., upward in FIG. 1) in which the seating surface 24S moves away from the valve seat surface 21S.

When a voltage is applied to the piezoelectric stack 231, the piezoelectric stack 231 expands. The piezoelectric stack 231 then presses, against the urging force of the urging member, the valving element 24 via the spherical member 27 and the plunger 28 in a second direction (e.g. downward) opposite to the first direction. Eventually, the seating surface 24S of the valving element 24 is seated on the valve seat surface 21S.

In a state before the seating surface 24S is seated on the valve seat surface 21S, that is, in a state where a gap is formed between the valve seat surface 21S and the seating surface 24S, the liquid material LQ is fed to the gas-liquid mixing portion 29 (gas-liquid mixing chamber 29a) via the liquid material feeding passage 21a and the carrier gas CG is fed to the gas-liquid mixing portion 29 via the carrier gas feeding passage 21b. In the gas-liquid mixing portion 29, the liquid material LQ and the carrier gas CG are mixed to produce the gas-liquid mixture MG and the produced gas-liquid mixture MG is then discharged to the connection portion 4 via the gas-liquid mixture discharging passage 21c to move on to the vaporization portion 3.

On the other hand, when the seating surface 24S is seated on the valve seat surface 21S, the flow rate of the liquid material LQ becomes zero. The carrier gas CG, on the other hand, flows from the carrier gas feeding passage 21b via the communication passage 21d provided in the valve seat surface 21S to the gas-liquid mixture discharging passage 21c. In other words, in a state where the seating surface 24S is seated on the valve seat surface 21S, only the carrier gas CG flows through the gas-liquid mixture discharge passage 21c to be discharged. Note that, a configuration is also possible where, in a state where the seating surface 24S is seated on the valve seat surface 21S, (as with the liquid material LQ) the flow rate of the carrier gas CG too becomes zero (i.e., neither the liquid material LQ nor the carrier gas CG flows).

In this way, with the configuration where the actuator 23 moves the valving element 24, by applying to the actuator 23 a voltage according to a predetermined openness of the valve, it is possible to achieve the above openness of the valve. This helps properly regulate (control) the flow rate of the liquid material LQ that is fed to the gas-liquid mixing portion 29 to be mixed with the carrier gas CG and then discharged with the carrier gas CG.

### 1-2. Vaporization Portion

The vaporization portion 3 heats and vaporizes the liquid material LQ in the gas-liquid mixture MG discharged through the gas-liquid mixture discharging passage 21c in the flow control valve 2. The vaporization portion 3 includes a vaporizing chamber 31 and a nozzle N. The vaporizing chamber 31 is a chamber for vaporizing the liquid material LQ in the gas-liquid mixture MG and is heated by a heater not shown. The nozzle N is located upstream of the vaporizing chamber 31 to communicate with the vaporizing chamber 31 and atomizes the above gas-liquid mixture MG into the vaporizing chamber 31.

### 1-3. Connection Portion

The connection portion 4 connects the gas-liquid mixture discharging passage 21c in the flow control valve 2 with the vaporization portion 3. In the configuration in FIG. 1, the connection portion 4 is configured to have a connecting pipe 41. The connecting pipe 41 is a pipe in an annular shape that connects the gas-liquid mixture discharging passage 21c with the nozzle N. The connection portion 4 is formed of a metal material such as stainless steel.

Here, the gas-liquid mixture discharging passage 21c in the flow control valve 2 and the connection portion 4 together constitute a flow passage FP through which the gas-liquid mixture MG produced in the gas-liquid mixing portion 29 flows. In other words, the flow passage FP is configured to include the gas-liquid mixture discharging passage 21c and the connection portion 4. Thus, it can be understood that the vaporization portion 3 heats and vaporizes the liquid material LQ in the gas-liquid mixture MG flowing through the flow passage FP.

The cooling portion 5 cools the flow passage FP. The cooling portion 5 cools, in particular, the connection portion 4 of the flow passage FP. The cooling portion 5 is configured to have a case 51, an inlet 52, and an outlet 53.

The case 51 covers around the connection portion 4. In the embodiment, the case 51 is located around the connecting pipe 41 and is formed unitarily with the connecting pipe 41. In other words, the case 51 and the connecting pipe 41 are configured as a doble pipe that has the case 51 as an outer pipe and the connecting pipe 41 as an inner pipe.

The inlet 52 is a port (opening portion) for introducing a carrier gas CG into the case 51. As the carrier gas CG introduced into the case 51, the same gas is used as the carrier gas CG mixed with the liquid material LQ in the flow control valve 2. The outlet 53 is a port (opening portion) for introducing out (discharging) the carrier gas CG from the case 51. The inlet 52 is located closer than the outlet 53 to the vaporization portion 3.

Within the case 51 in the cooling portion 5, passing the carrier gas CG from the inlet 52 to the outlet 53 allows the cooling of the connection portion 4 (connecting pipe 41) enclosed in the case 51. For example, even if the vaporization portion 3 becomes as hot as 200 °C, introducing the carrier gas CG at the temperature (e.g., around room temperature) of the environment where the liquid material vaporizer 1 is installed allows the connection portion 4 to be cooled. Thus, even if the vaporization portion 3 becomes hot, less of the heat in the vaporization potion 3 transmits via the connection portion 4 upstream (toward the gas-liquid mixing portion 29 of the flow control valve 2). This helps reduce the likelihood of the liquid material LQ in the gas-liquid mixture MG thermally decomposing or degenerating before the gas-liquid mixture MG is fed to the vaporization portion 3.

In particular, when a material (e.g., strontium) with a low vapor pressure is used as the liquid material LQ, the vaporization portion 3 needs to be heated to a higher temperature in order to evaporate the liquid material LQ in the vaporization portion 3. Thus, the configuration of the embodiment where, with a view to reducing thermal decomposition of the liquid material LQ, the cooling portion 5 cools the connection portion 4 is effective especially when a material with a low vapor pressure is used as the liquid material LQ.

In the embodiment, as shown in FIG. 1, the cooling portion 5 communicates with the carrier gas feeding passage 21b in the flow control valve 2. For example, fastening together the cooling portion 5 and the body block 21 in the flow control valve 2 with a bolt via a flange not shown permits the cooling portion 5 and the carrier gas feeding passage 21b to communicate with each other. Specifically, the bolt fastening permits the case 51 in the cooling portion 5 to communicate with the carrier gas feeding passage 21b via the outlet 53.

### 2. Liquid Material Vaporization Method

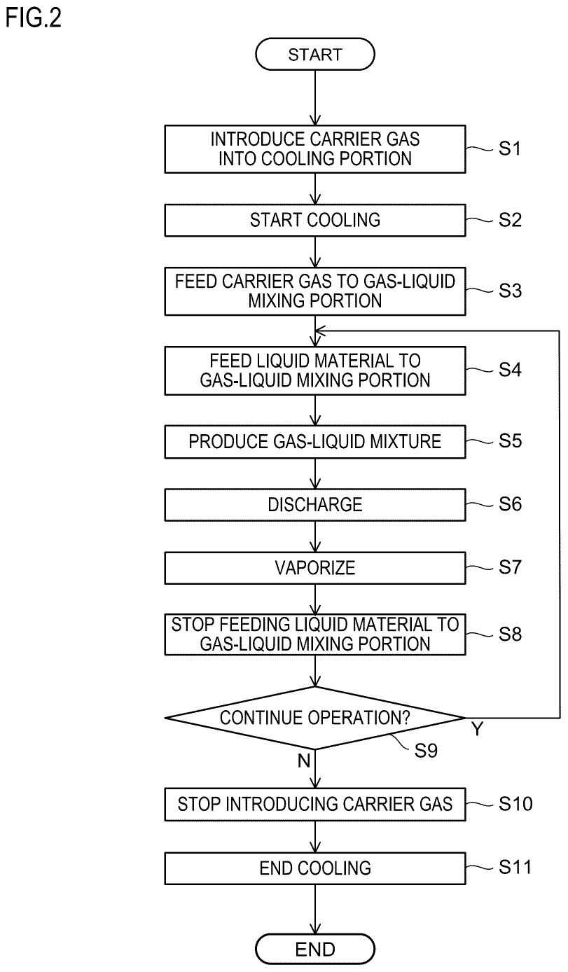

FIG. 2 is a flow chart showing the sequence of steps in a liquid material vaporization method for vaporizing the liquid material LQ using the liquid material vaporizer 1 with the configuration described above. Now, the liquid material vaporization method according to the embodiment will be described with reference to FIGS. 1 and 2.

First, the carrier gas CG is introduced into the cooling portion 5 (S1). Specifically, the carrier gas CG is introduced into the case 51 through the inlet 52 in the cooling portion 5. Then, the cooling portion 5 starts to cool the flow passage FP (in particular, connection portion 4) (S2: cooling step). The carrier gas CG introduced into the cooling portion 5 and having cooled the connection portion 4 is fed to the gas-liquid mixing portion 29 via the carrier gas feeding passage 21b (S3: carrier gas feeding step). On the other hand, the liquid material LQ is fed to the gas-liquid mixing portion 29 via the liquid material feeding passage 21a (S4: liquid material feeding step).

In the gas-liquid mixing portion 29, the liquid material LQ and the carrier gas CG are mixed together to produce the gas-liquid mixture MG (S5: gas-liquid mixture producing step).

The gas-liquid mixture MG produced in the gas-liquid mixing portion 29 is discharged via the gas-liquid mixture discharging passage 21c to the connection portion 4 (connecting pipe 41) (S6: discharging step). The liquid material LQ in the gas-liquid mixture MG, which is discharged via the gas-liquid mixture discharging passage 21c to be fed through the connection portion 4 to the vaporization portion 3, is heated and vaporized in the vaporization portion 3 (S7: vaporizing step).

Next, the feeding of the liquid material LQ to the gas-liquid mixing portion 29 is stopped (S8). Note that S8 can be done as necessary. Subsequently, if the operation of vaporizing the liquid material LQ in the vaporization portion 3 is continued (Yes in S9), a return is made to S4 to repeat S4 and the following steps (since S3 is underway all the time). Incidentally, in a configuration where, in the flow control valve 2, the flow rate of the carrier gas CG is zero with the seating surface 24S seated on the valve seat surface 21S, a jump can be made from S9 to S3 to repeat S3 and the following steps.

When the above operation is not continued (No in S9), the introduction of the carrier gas CG into the cooling portion 5 is stopped (S10) and the cooling of the connection portion 4 by the cooling portion 5 is ended (S11). This completes the sequence of steps.

### 3. Effect

As described above, in the embodiment, the cooling portion 5 communicates with the carrier gas feeding passage 21b in the flow control valve 2. Thus, the carrier gas CG to be mixed with the liquid material LQ in the flow control valve 2 can be fed from the cooling portion 5 via the carrier gas feeding passage 21b to the gas-liquid mixing portion 29 (see S2 and S3). That is, the carrier gas CG for mixing with the liquid material LQ can be used also as the gas for cooling the flow passage FP (in particular, the connection portion 4) in the cooling portion 5. This eliminates the need to prepare a refrigerant dedicated to cooling the flow passage FP apart from the carrier gas CG for mixing with the liquid material LQ. Thus, no extra equipment is needed either for introducing the refrigerant or for disposing of the refrigerant after cooling. It is thus possible to suppress an increase in the size of semiconductor processing equipment incorporating the liquid material vaporizer 1 as well as in the cost for the installation of equipment as mentioned above. Further, since no refrigerant dedicated to cooling is used, no refrigerant is wasted by disposal as mentioned above.

In addition, since the carrier gas CG is used for cooling the flow passage FP, the heat in the vaporization portion 3 preheats the carrier gas CG. Thus, before the carrier gas CG is fed from the cooling portion 5 via the carrier gas feeding passage 21b to the gas-liquid mixing portion 29 and the gas-liquid mixture MG after mixing with the liquid material LQ is vaporized in the vaporization portion 3, the liquid material LQ can be heated to a temperature at which it vaporizes easily (in a temperature range free from thermal decomposition or the like). This is expected to improve also the vaporization properties of the liquid material LQ in the vaporization portion 3.

Moreover, in the embodiment, since the case 51 encloses around the connection portion 4 of the flow passage FP, the connection portion 4 has an enclosed space formed around it. The carrier gas CG flows within this space and this helps reduce diffusion of the carrier gas CG that occurs in the open space. It is thus possible to suppress loss in the cooling by the carrier gas CG and wasteful consumption of the carrier gas CG. Also, since the case 51 communicates with the carrier gas feeding passage 21b, the carrier gas CG after flowing in the case 51 and cooling the connection portion 4 can be reliably fed via the carrier gas feeding passage 21b to the gas-liquid mixing portion 29.

As shown in FIG. 1, the carrier gas feeding passage 21b is connected to the outlet 53 of the cooling portion 5. With this configuration, the carrier gas CG introduced through the inlet 52 of the cooling portion 5 into the case 51 can be fed via the outlet 53 to the carrier gas feeding passage 21b. It is thus possible to securely achieve a configuration where the case 51 communicates with the carrier gas feeding passage 21b.

In particular, as shown in FIG. 1, in the configuration where the inlet 52 is located closer than the outlet 53 to the vaporization portion 3, in the cooling step of S2, it is possible to cool the connection portion 4 by passing the carrier gas CG through the case 51 from its side near the vaporization portion 3 (downstream along the flowing direction of the gas-liquid mixture MG flowing in the connection portion 4) to its side away from the vaporization portion 3 (upstream along the flowing direction of the gas-liquid mixture MG).

This allows the downstream part of the connection portion 4, to which the heat of the vaporization portion 3 easily transmits, to be efficiently cooled earlier than (preferentially to) its upstream part. This reliably hinders the heat in the vaporization portion 3 from transmitting via the connection portion 4 to the upstream part, and thereby helps reliably reduce the likelihood of the liquid material LQ thermally decomposing or degenerating before vaporization in the vaporization portion 3.

The inlet 52 can be located opposite from the vaporization portion 3 with respect to the outlet 53. Note however that this positional relationship requires a long flow passage for communication between the outlet 53 and the carrier gas feeding passage 21b.

### 4. Regarding Preferable Position of Inlet

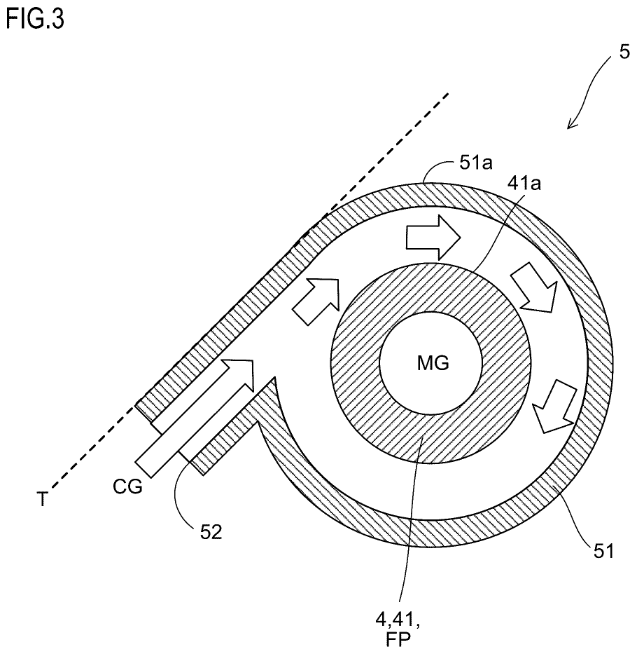

FIG. 3 is a sectional view of the cooling portion 5 as cut along a section perpendicular to the flowing direction of the gas-liquid mixture MG in the connection portion 4 (connecting pipe 41). It is preferable that, as shown in FIG. 3, the inlet 52 of the cooling portion 5 be positioned so as to align with a tangential line T to the outer circumferential surface 51a of the case 51. Note that the outer circumferential surface 51a of the case 51 is a cylindrical surface covering, across a gap, the outer circumferential surface 41a of the cylindrical connecting pipe 41 in the connection portion 4.

With this configuration, the carrier gas CG is introduced through the inlet 52 into the case 51 from a direction along the tangential line T to the outer circumferential surface 51a of the case 51. This makes it easy to pass the carrier gas CG so as to swirl around the connection portion 4 in the case 51. With the swirling carrier gas CG, it is possible to cool the connection portion 4 with the carrier gas CG in such a way as to embrace it along the circumferential direction, thereby improving the cooling efficiency in the connection portion 4.

From what has been described above, it can be understood that, with the configuration provided with the cooling portion 5 as shown in FIG. 3, in the cooling step of S2, it is possible to cool the connection portion 4 by passing the carrier gas CG into the case 51 from a direction along the tangential line T of the outer circumferential surface 51a of the case 51 enclosing around the connection portion 4 in the section mentioned above. This brings an effect of improving the cooling efficiency in the connection portion 4.

### 2. Another Structure of Liquid Material Vaporizer

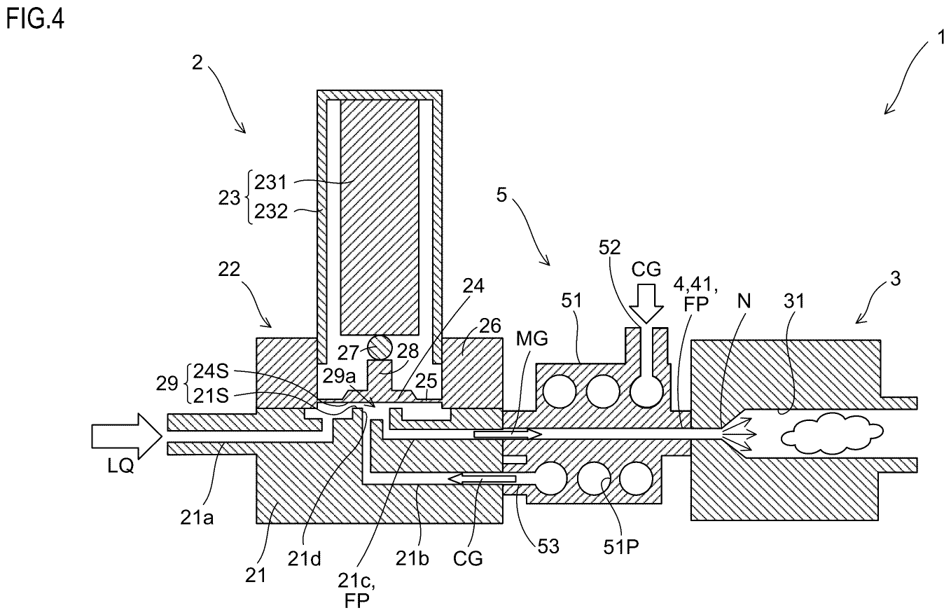

FIG. 4 is a schematic sectional view of another structure of the liquid material vaporizer 1 according to the embodiment. The liquid material vaporizer 1 in FIG. 4 has a helical gas flow passage 51P in a case 51 of a cooling portion 5 and otherwise has a configuration similar to that in FIG. 1.

The gas flow passage 51P is a flow passage formed helically around the connection portion 4 (connecting pipe 41) in the case 51. The case 51 with such a gas flow passage 51P can be produced by, for example, configuring the case 51 from a plurality of case segments, and putting those case segments together by welding or bolt-fastening. The helical gas flow passage 51P communicates with the inlet 52 and the outlet 53 described previously.

With the configuration in FIG. 4, when introduced through the inlet 52 into the case 51, the carrier gas CG flows, through the case 51, helically around the connection portion 4 along the helical gas flow passage 51P. This makes it possible to cool the connection portion 4 with the carrier gas CG in such a way as to embrace it along the circumferential direction, thereby improving the cooling efficiency in the connection portion 4.

From what has been described above, it can be understood that, with the configuration in FIG. 4, in the cooling step of S2, passing the carrier gas CG through the helical gas flow passage 51P formed around the connection portion 4 in the case 51 enclosing around the connection portion 4 achieves the cooling of the connection portion 4. This brings an effect of improving the cooling efficiency in the connection portion 4.

### 3. Still Another Structure of Liquid Material Vaporizer

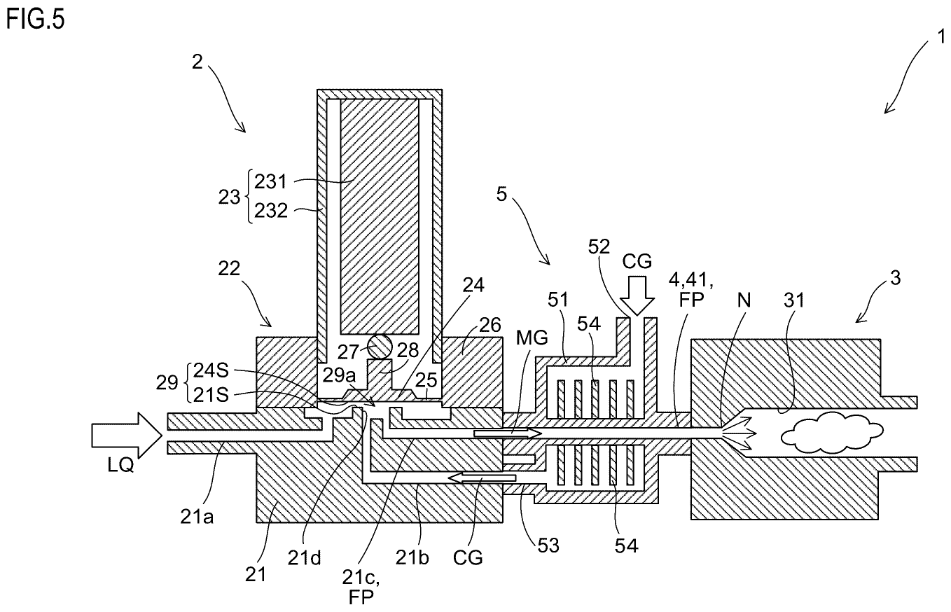

FIG. 5 is a schematic sectional view of another structure of the liquid material vaporizer 1 according to the embodiment. The liquid material vaporizer 1 in FIG. 5 has a fin 54 in a case 51 of a cooling portion 5 and otherwise has a configuration similar to that in FIG. 1.

The fin 54 is a heat sink in the form of a flat plate and a plurality of fins 54 are provided in the case 51. The fins 54 are coupled to the outer circumferential surface 41a (see FIG. 3) of the connection portion 4 (connecting pipe 41), for example, by welding. In addition, the fins 54 are disposed on the outer circumferential surface 41a in an array at predetermined intervals along the extending direction of the connection portion 4 in the case 51. The fins 54 can be formed of the same metal material as the connection portion 4 or of a metal material (e.g., aluminum, copper, or an alloy of these) with higher thermal conductivity than the metal forming the connection portion 4.

Providing, in the case 51, a plurality of fins 54 coupled to the outer circumferential surface 41a of the connection portion 4 is substantially equivalent to increasing the surface area of the outer circumferential surface 41a of the connection portion 4 by the surface area of the plurality of fins 54. Thus, in the case 51, by exposing to the carrier gas CG the fins 54 with a large surface area as well as the outer circumferential surface 41a of the connection portion 4, it is possible to efficiently dissipate the heat of the connection portion 4. This helps improve the cooling efficiency of the connection portion 4.

In the liquid material vaporizer 1 described above, the vaporization portion 3 includes the nozzle N, the connection portion 4 includes the connecting pipe 41, and the cooling portion 5 cools the connection portion 4 (connecting pipe 41). In this configuration, the cooling portion 5 communicates with the carrier gas feeding passage 21b, and this makes it possible to effectively use the carrier gas CG for mixing with the liquid material LQ as a gas for cooling the connection portion 4. This brings the effects of the embodiment described above, such as of suppressing an increase in the size and cost of semiconductor processing equipment incorporating the liquid material vaporizer 1.

### 4. Yet Another Structure of Liquid Material Vaporizer

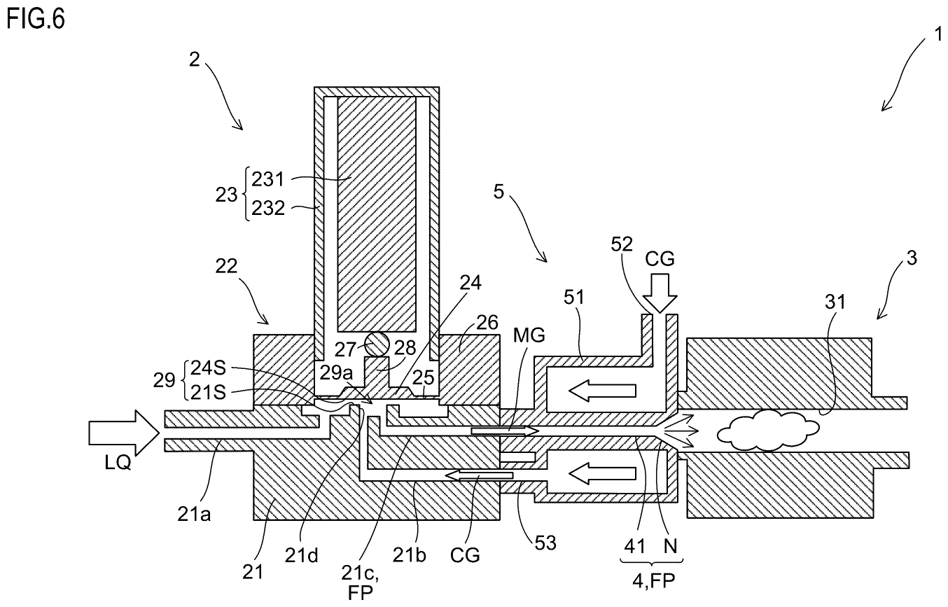

FIG. 6 is a schematic sectional view of yet another structure of the liquid material vaporizer 1 according to the embodiment. In the liquid material vaporizer 1 in FIG. 6, the nozzle N is provided in the connection portion 4, that is, outside the vaporization portion 3 and thus the cooling portion 5 cools the connection portion 4 including the nozzle N. Otherwise, it has a configuration similar to that in FIG. 1. Needless to say, the configurations of the cooling portion 5 shown in FIGS. 3 to 5 can be applied also to the liquid material vaporizer 1 in FIG. 6.

In the liquid material vaporizer 1 in FIG. 6, the connection portion 4 includes the connecting pipe 41 and the nozzle N. The nozzle N is located between the connecting pipe 41 and the vaporization portion 3 and atomizes the gas-liquid mixture MG into the vaporizing chamber 31 in the vaporization portion 3. That is, the nozzle N is located outside the vaporization portion 3, upstream of the vaporization portion 3. The case 51 of the cooling portion 5 covers both the connecting pipe 41 and the nozzle N.

Also with the configuration in FIG. 6, as with the configuration in FIG. 1, communication between the cooling portion 5 and the carrier gas feeding passage 21b allows the carrier gas CG for mixing with the liquid material LQ to be efficiently used as a gas for cooling the connection portion 4 and this brings the effects of the embodiment described above, such as of suppressing an increase in the size and cost of semiconductor processing equipment incorporating the liquid material vaporizer 1.

### 5. Notes

In the configuration where the nozzle N is provided outside (upstream of) the vaporization portion 3, the connection portion 4 can be composed only of the nozzle N. In other words, a configuration is also possible where the connection portion 4 does not include the connecting pipe 41 and the gas-liquid mixture discharging passage 21c in the flow control valve 2 is connected to the vaporization portion 3 via the nozzle N. With this configuration, covering around the nozzle N with the case 51 and passing the carrier gas CG through the case 51 allows the cooling of the nozzle N. Thus, communication between the cooling portion 5 with the case 51 so designed and the carrier gas feeding passage 21b brings an effect similar to that achieved with the embodiment.

While in the embodiment, the flow control valve 2 included in the liquid material vaporizer 1 is of a normal open type, instead, a flow control valve 2 of a normal close type can be employed in the configuration of the embodiment, where the carrier gas feeding passage 21b communicates with the cooling portion 5. In this case, the gas-liquid mixing portion 29 can be given a configuration properly modified to suit the normal close type.

The liquid material vaporizer 1 according to the embodiment includes the carrier gas feeding passage 21b communicating with the cooling portion 5 in the configuration employing an internal mixing method in which, inside the flow control valve 2, the liquid material LQ and the carrier gas CG are mixed together to produce the gas-liquid mixture MG. Instead, also with an external mixing method in which, outside the flow control valve 2, the liquid material LQ is mixed with the carrier gas CG, the carrier gas CG having cooled the nozzle N in the cooling portion 5 can be mixed with the liquid material LQ, for example, at the time of atomization into the vaporizing chamber 31. This, too, brings an effect similar to that achieved with the embodiment.

While an embodiment of the present invention is described above, this is not meant to limit the scope of the present invention, which can thus be implemented with expansions or modifications made without departing from the spirit of the present invention.

### INDUSTRIAL APPLICABILITY

The present invention finds applications in a vaporizer incorporated, for example, in a stage preceding semiconductor processing equipment.

### REFERENCE CHARACTERS LIST

1 liquid material vaporizer
3 vaporization portion
4 connection portion
5 cooling portion
21a liquid material feeding passage
21b carrier gas feeding passage
21c gas-liquid mixture discharging passage
29 gas-liquid mixing portion
31 vaporizing chamber
41 connecting pipe
41a outer circumferential surface
51 case
51P gas flow passage
51a outer circumferential surface
52 inlet
53 outlet
54 fin
CG carrier gas
FP flow passage
LQ liquid material
MG gas-liquid mixture
N nozzle
T tangential line

1. A liquid material vaporizer comprising:
a gas-liquid mixing portion for mixing together a liquid material and a carrier gas to produce a gas-liquid mixture;
a carrier gas feeding passage for feeding the carrier gas to the gas-liquid mixing portion;
a flow passage through which the gas-liquid mixture produced in the gas-liquid mixing portion flows;
a vaporization portion for heating and vaporizing the liquid material in the gas-liquid mixture flowing through the flow passage; and
a cooling portion for cooling the flow passage, wherein
the cooling portion communicates with the carrier gas feeding passage.

2. The liquid material vaporizer according to claim 1, wherein
the flow passage includes:
a gas-liquid mixture discharging passage for discharging the gas-liquid mixture produced in the gas-liquid mixing portion; and
a connection portion for connecting together the gas-liquid mixture discharging passage and the vaporization portion, and
the cooling portion cools the connection portion.

3. The liquid material vaporizer according to claim 2, wherein
the cooling portion has a case covering around the connection portion and
the case communicates with the carrier gas feeding passage.

4. The liquid material vaporizer according to claim 3, wherein
the cooling portion includes:
an inlet for introducing the carrier gas into the case; and
an outlet for discharging the carrier gas out of the case, and
the carrier gas feeding passage is connected to the outlet.

5. The liquid material vaporizer according to claim 4, wherein
the inlet is located closer than the outlet to the vaporization portion.

6. The liquid material vaporizer according to claim 4, wherein
in a section perpendicular to a flowing direction of the gas-liquid mixture in the connection portion,
the inlet is located so as to align with a tangential line to an outer circumferential surface of the case.

7-11. (canceled)

12. The liquid material vaporizer according to claim 5, wherein
in a section perpendicular to a flowing direction of the gas-liquid mixture in the connection portion,
the inlet is located so as to align with a tangential line to an outer circumferential surface of the case.

13. The liquid material vaporizer according to claim 3, wherein
the case has a gas flow passage formed helically around the connection portion.

14. The liquid material vaporizer according to claim 4, wherein
the case has a gas flow passage formed helically around the connection portion.

15. The liquid material vaporizer according to claim 5, wherein
the case has a gas flow passage formed helically around the connection portion.

16. The liquid material vaporizer according to claim 6, wherein
the case has a gas flow passage formed helically around the connection portion.

17. The liquid material vaporizer according to claim 7, wherein
the case has a gas flow passage formed helically around the connection portion.

18. The liquid material vaporizer according to claim 2, wherein
the cooling portion has a fin coupled to an outer surface of the connection portion.

19. The liquid material vaporizer according to claim 3, wherein
the cooling portion has a fin coupled to an outer surface of the connection portion.

20. The liquid material vaporizer according to claim 4, wherein
the cooling portion has a fin coupled to an outer surface of the connection portion.

21. The liquid material vaporizer according to claim 5, wherein
the cooling portion has a fin coupled to an outer surface of the connection portion.

22. The liquid material vaporizer according to claim 6, wherein
the cooling portion has a fin coupled to an outer surface of the connection portion.

23. The liquid material vaporizer according to claim 2, wherein
the vaporization portion includes a nozzle for atomizing the gas-liquid mixture into a vaporizing chamber and
the connection portion includes a connecting pipe for connecting together the gas-liquid mixture discharging passage and the nozzle.

24. The liquid material vaporizer according to claim 2, wherein
the connection portion includes:
a connecting pipe connected to the gas-liquid mixture discharging passage; and
a nozzle located between the connecting pipe and the vaporization portion, the nozzle atomizing the gas-liquid mixture into the vaporizing chamber in the vaporization portion.

25. A liquid material vaporization method comprising:
a gas-liquid mixture producing step of mixing together a liquid material and a carrier gas in a gas-liquid mixing portion to produce a gas-liquid mixture;
a vaporizing step of heating and vaporizing, in a vaporization portion, the liquid material in the gas-liquid mixture produced in the gas-liquid mixing portion and fed through a flow passage to the vaporization portion;
a cooling step of cooling the flow passage by feeding the carrier gas; and
a carrier gas feeding step of feeding the carrier gas having cooled the flow passage in the cooling step via a carrier gas feeding passage to the gas-liquid mixing portion.
